(19) United States
(12) Patent Application Publication
(10) Pub. No.: US 2026/0247585 A1
(43) Pub. Date: Aug. 20, 2026

(54) LIQUID COOLING SYSTEM AND METHOD FOR CONTROLLING THEREOF

(71) Applicant: Delta Electronics, Inc., Taoyuan City (TW)

(72) Inventors: Sheng-Chi WU, Taoyuan City (TW); Cih-Ping WANG, Taoyuan City (TW); Li An CHUNG, Taoyuan City (TW); Chih-Hung TSAI, Taoyuan City (TW); Jen Te LIANG, Taoyuan City (TW)

(21) Appl. No.: 19/442,206

(22) Filed: Jan. 7, 2026

Related U.S. Application Data
(60) Provisional application No. 63/760,321, filed on Feb. 19, 2025.

(30) Foreign Application Priority Data
May 29, 2025 (CN) 202510706640.2

(51) Int. Cl. H05K 7/20

(52) U.S. Cl. CPC H05K 7/20836; H05K 7/20263; H05K 7/20272; H05K 7/20781

(57) ABSTRACT

A liquid cooling system for cooling server system includes a first flow meter for detecting an inlet flow rate of coolant from the server system into the liquid cooling system, a second flow meter for detecting an outlet flow rate of coolant, a radiator with fans, a reservoir with at least one pump, and a controller for detecting a differential flow between the inlet and outlet flow rate, and for recording the inlet or outlet flow rate in a real-time value as a comparison value. The radiator receives high-temperature coolant from the server system and operates the fans to cool the coolant. The reservoir receives the cooled coolant and feeds it to the server system. If the inlet or outlet flow rate rises to the first constant times the comparison value before the differential flow reaches the set differential pressure, the fan speed is increased.

### CROSS REFERENCE TO RELATED APPLICATIONS

This application claims the benefit of U.S. provisional Application No. 63/760,321, filed Feb. 19, 2025, the entirety of which is incorporated by reference herein.

This application claims priority of China patent application No. 202510706640.2, filed May 29, 2025, the entirety of which is incorporated by reference herein.

### TECHNICAL FIELD

The present invention relates to a liquid cooling system and method for controlling thereof, and, in particular, it relates to a liquid cooling system that controls the rotating speed of fans to facilitate cooling, and a method for controlling the liquid cooling system.

### BACKBGOUND

In conventional liquid cooling systems, the water supply temperature is controlled by a controller (e.g., a PID controller, etc.). In some liquid cooling systems equipped with a fan, the speed of the fan must be adjusted accordingly when the water supply temperature changes, so that the temperature remains at the desired temperature.

However, the conventional control method mentioned above needs to control the fan speed via a temperature closed-loop control system. The disadvantage of the temperature closed-loop control system is that heat-dissipation efficiency is low due to the large fluctuation of water temperature and the long response time.

Furthermore, when servers are used as cooling objects, if the number of servers changes, or when servers are replaced, the operating heat of the servers will change significantly. However, conventional liquid cooling systems cannot adjust accordingly in real time, resulting in low heat-dissipation efficiency.

### BRIEF SUMMARY

In order to solve the shortcomings of large fluctuation of water temperature and long response time, the present invention proposes a method for adjusting the fan speed mainly by flow control.

According to some embodiments of the present disclosure, a liquid cooling system for cooling a server system is provided, including: a first flow meter for detecting an inlet flow rate of coolant from the server system into the liquid cooling system, a second flow meter for detecting an outlet flow rate of coolant out of the liquid cooling system, a radiator with a plurality of fans, a reservoir with at least one pump, and a controller for detecting a differential flow between the inlet flow rate and the outlet flow rate, and for recording the inlet flow rate or outlet flow rate in a real-time value as a comparison value. The radiator receives high-temperature coolant from the server system and operates the fans to cool the coolant. The reservoir receives the cooled coolant and feeds it from the liquid cooling system to the server system by operating the pump. If the inlet or outlet flow rate rises to a first constant times the comparison value before the differential flow reaches a set differential pressure, the rotating speed of each of the fans is increased.

In some embodiments, the controller is further used for controlling an operation speed of the pump, so that the differential flow reaches the set differential pressure. When the differential flow reaches the set differential pressure, the controller starts to record the real-time value of the inlet flow rate or the outlet flow rate.

In some embodiments, the liquid cooling system further includes a first thermometer for detecting an inlet temperature of the coolant into the liquid cooling system, and a second thermometer for detecting an outlet temperature of the coolant out of the liquid cooling system. The controller is further used for detecting a temperature difference between the inlet temperature and the outlet temperature. The controller is further used for determining that a heat load of the server system has increased when the temperature difference is greater than a set temperature difference. The controller stops the recording of the real-time value of the inlet flow rate or the outlet flow rate and increasing the operation speed of the pump when the heat load is determined to have increased and the inlet flow rate or the outlet flow rate is determined to have been reduced.

In some embodiments, the controller uses the real-time value last recorded in a memory as the comparison value when the real-time value of the inlet flow rate or the outlet flow rate stops being recorded.

In some embodiments, the controller is further used for increasing the rotating speed of each of the fans to a set rotating speed. The set rotating speed is a second constant times the rotating speed before the increase. Both the first constant and the second constant are greater than 1.

In some embodiments, the liquid cooling system further includes a first thermometer for detecting an inlet temperature of the coolant from the server system into the liquid cooling system, and a second thermometer for detecting an outlet temperature of the coolant out of the liquid cooling system. When each of the fans is rotating at the set rotating speed, the controller is further used for combining a set outlet temperature, the inlet temperature, and an increment value to obtain a first rotating speed variable.

In some embodiments, the controller is further used for superposing the outlet temperature and the set outlet temperature to obtain a first controlling value, and adjusting the first controlling value via a PID computing unit to obtain a second controlling value. The controller is further used for superposing the second controlling value and the real-time value of the rotating speed of the fans to obtain a second rotating speed variable. The controller is further used for superposing the first rotating speed variable and the second rotating speed variable to slightly adjust the rotating speed of each of the fans.

According to other embodiments of the present disclosure, a method for controlling a liquid cooling system for cooling a server system is provided. The method includes detecting an inlet flow rate of coolant from the server system into the liquid cooling system. The method includes detecting an outlet flow rate of coolant out of the liquid cooling system. The method includes cooling the high-temperature coolant from the server system by operating a plurality of fans via a radiator that includes the fans. The method includes operating at least one pump, so that the cooled coolant is fed from the liquid cooling system to the server system. The method includes detecting a differential flow between the inlet flow rate and the outlet flow rate. The method includes recording the inlet flow rate or the outlet flow rate in a real-time value as a comparison value. If the inlet or outlet flow rate rises to a first constant times the comparison value before the differential flow reaches a set differential pressure, the method includes increasing the rotating speed of each of the fans.

In some embodiments, the method further includes controlling an operation speed of the pump, so that the differential flow reaches the set differential pressure. When the differential flow reaches the set differential pressure, start recording the real-time value of the inlet flow rate or the outlet flow rate.

In some embodiments, the method further includes detecting a temperature difference between the inlet temperature and the outlet temperature. The method further includes determining that a heat load of the server system has increased when the temperature difference is greater than a set temperature difference. The method further includes stopping the recording of the real-time value of the inlet flow rate or the outlet flow rate and increasing the operation speed of the pump when the heat load is determined to have increased and the inlet flow rate or the outlet flow rate is determined to have been reduced.

In some embodiments, the method further includes increasing the rotating speed of each of the fans to a set rotating speed. The set rotating speed is a second constant times the rotating speed before the increase. Both the first constant and the second constant are greater than 1.

In some embodiments, the method further includes detecting an inlet temperature of the coolant from the server system into the liquid cooling system. The method further includes detecting an outlet temperature of the coolant out of the liquid cooling system. When each of the fans is rotating at the set rotating speed, combine a set outlet temperature, the inlet temperature, and an increment value to obtain a first rotating speed variable.

In some embodiments, the method further includes: superposing the outlet temperature and the set outlet temperature to obtain a first controlling value; adjusting the first controlling value via a PID computing unit to obtain a second controlling value; superposing the second controlling value and the real-time value of the rotating speed of the fans to obtain a second rotating speed variable; and superposing the first rotating speed variable and the second rotating speed variable to slightly adjust the rotating speed of each of the fans.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 shows an exemplary schematic view of the liquid cooling system and the server system, in accordance with some embodiments of the present disclosure.

FIG. 2A shows a flow chart of the control method of the liquid cooling system, in accordance with some embodiments of the present disclosure.

FIG. 2B shows a flow chart of the method for controlling the fan according to flow rate, in accordance with some embodiments of the present disclosure.

FIG. 3 shows a block diagram of the controller in the liquid cooling system, in accordance with some embodiments of the present disclosure.

FIG. 4 is a flow chart of the control method corresponding to the block diagram of FIG. 3.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

In addition, the present disclosure may repeat reference numerals and/or letters in the various embodiments. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “vertical,” “above,” “over,” “below,”, “bottom,” etc. as well as derivatives thereof (e.g., “downwardly,” “upwardly,” etc.) are used for ease of the present disclosure of one feature relationship to another feature. The spatially relative terms are intended to cover different orientations of the device including the features.

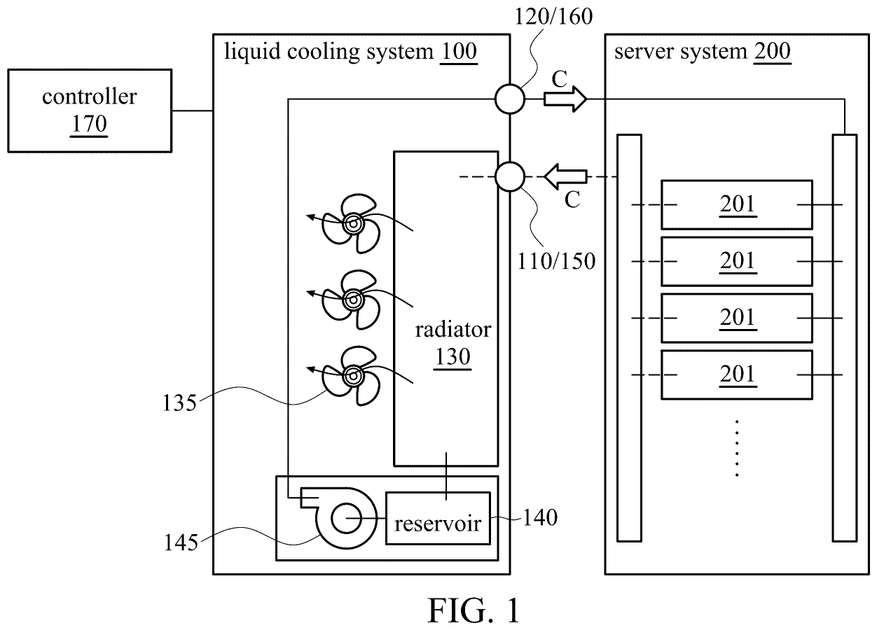

Referring to FIG. 1, FIG. 1 shows an exemplary schematic view of the liquid cooling system 100 and the server system 200, in accordance with some embodiments of the present disclosure. In embodiments according to the present disclosure, the liquid cooling system 100 is used for cooling the server system 200. Specifically, through the coolant C that is circulated in the liquid cooling system 100 and the server system 200, the heat generated by the server system 200 is transported to the liquid cooling system 100. The coolant C is cooled by the heat dissipation equipment inside the liquid cooling system 100, and the cooled coolant C is sent into the server system 200 to achieve the of cooling the server system 200. In FIG. 1, the solid lines indicate the cooled coolant C, and the dotted lines indicate the coolant C after absorbing heat.

As shown in FIG. 1, the server system 200 includes a plurality of servers 201. The coolant C flows through each of the servers 201 to collect the heat generated by the operation of the servers and transfers the heat to the liquid cooling system 100. The arrangement and location of the servers 201 are merely examples and are not particularly limited thereto. The number of servers 201 is not particularly limited and can be determined according to actual needs. The way the coolant C flows through the servers 201 is not particularly limited, and any suitable known configuration may be used.

As shown in FIG. 1, the liquid cooling system 100 includes a first flow meter 110, a second flow meter 120, a radiator 130, a reservoir 140, and a controller 170.

The first flow meter 110 is used for detecting the inlet flow rate of coolant C from the server system 200 into the liquid cooling system 100. The second flow meter 120 is used for detecting the outlet flow rate of coolant C out of the liquid cooling system 100. As shown in FIG. 1, for example, the first flow meter 110 is disposed at the high-temperature fluid inlet of the liquid cooling system 100 that communicates with the fluid outlet of the server system 200; the second flow meter 120 is disposed at the low-temperature fluid outlet of the liquid cooling system 100 that communicates with the fluid inlet of the server system 200. In some embodiments, the inlet flow rate and the outlet flow rate detected by the first flow meter 110 and the second flow meter 120 are transmitted to the controller 170.

The radiator 130 includes a plurality of fans 135. Although three fans 135 are shown in FIG. 1, the number of fans 135 is not particularly limited thereto and can be set according to actual needs. As shown in FIG. 1, the radiator 130 receives high-temperature coolant C from the server system 200 and operates each of the fans 135 to cool the coolant C. Specifically, as shown in FIG. 1, the heat in the coolant C is discharged outward (to the left side of the figure) through air flow, thereby achieving the effect of heat dissipation.

The reservoir 140 includes at least one pump 145. Although one pump 145 is shown in FIG. 1, the number of pump 145 is not particularly limited thereto and can be set according to actual needs. The reservoir 140 receives the cooled coolant C and feeds it from fluid outlet of the liquid cooling system 100 to the server system 200 by operating the pump 145. In some embodiments, the controller 170 may control the pump 145 to ensure that a sufficient flow of coolant C can be provided to the server system 200 to achieve a cooling effect.

The controller 170 may include a memory (not shown) for storing data or parameters related to controlling the liquid cooling system 100. In some embodiments, the controller 170 may be used for detecting a differential flow between the inlet flow rate and the outlet flow rate and recording the inlet flow rate and/or the outlet flow rate in a real-time value as a comparison value.

In addition, in some embodiments, the liquid cooling system 100 further includes a first thermometer 150 and a second thermometer 160. For example, as shown in FIG. 1, the first thermometer 150 may be disposed at the fluid inlet of the liquid cooling system 100 near the first flow meter 110; the second thermometer 160 may be disposed at the fluid outlet of the liquid cooling system 100 near the second flow meter 120. The first thermometer 150 is used for detecting the inlet temperature of the coolant C into the liquid cooling system 100; the second thermometer 160 is used for detecting the outlet temperature of the coolant C out of the liquid cooling system 100. In some embodiments, the inlet temperature and the outlet temperature detected by the first thermometer 150 and the second thermometer 160 are transmitted to the controller 170. Also, in such embodiments, the controller 170 may be used for detecting the temperature difference between the inlet temperature and the outlet temperature.

In FIG. 1, although the controller 170 is schematically depicted as a component connected to the liquid cooling system 100 from the outside, the present invention is not particularly limited thereto. The controller 170 can be disposed in a suitable location according to actual needs.

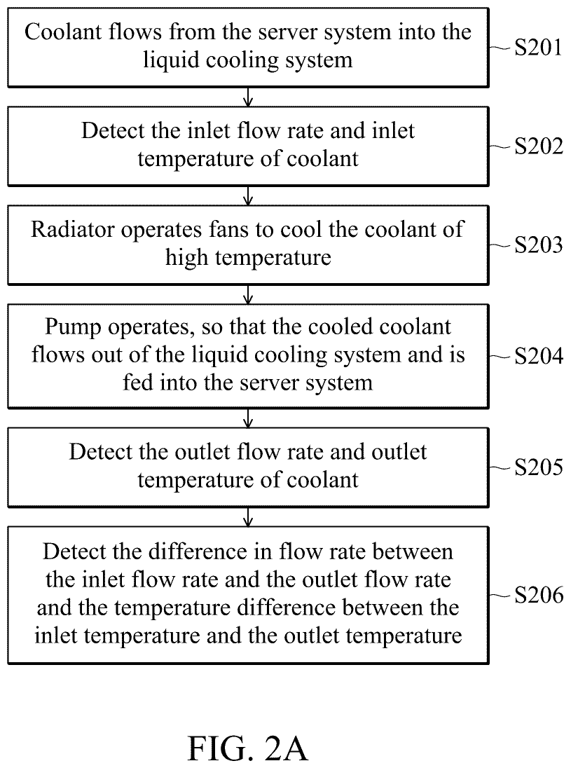

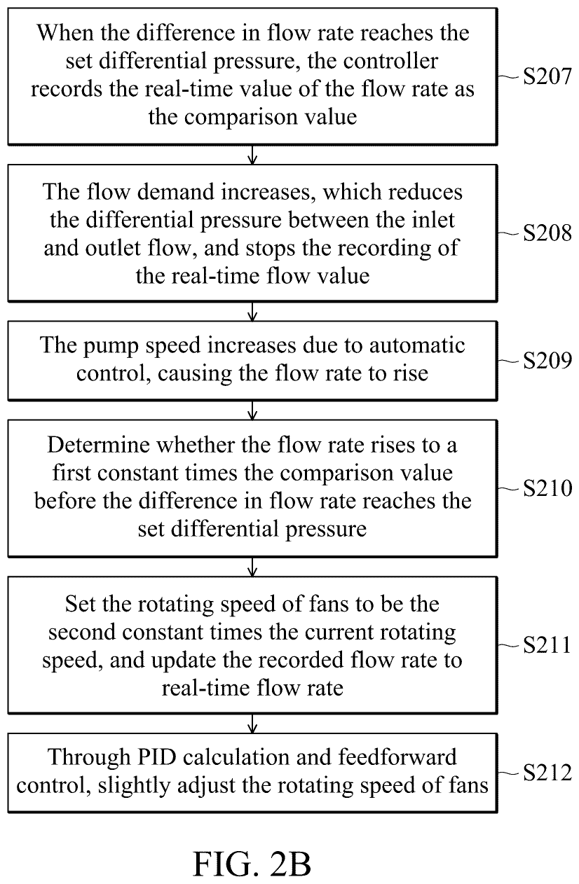

Next, the method for controlling the liquid cooling system 100 is described with respect to FIG. 2A. FIG. 2A shows a flow chart of the control method of the liquid cooling system 100, in accordance with some embodiments of the present disclosure.

First, the coolant C flows from the server system 200 through the fluid inlet of the liquid cooling system 100 into the liquid cooling system 100 (S201). At this time, through the first flow meter 110 and the first thermometer 150 that are disposed here, the inlet flow rate and the inlet temperature of the coolant C may be detected (S202).

Next, the radiator 130 operates each of the fans 135 to cool the coolant C of high temperature from the server system 200 (S203).

Then, at least one pump 145 in the reservoir 140 operates, so that the cooled coolant C flows through the fluid outlet out of the liquid cooling system 100 and feeds into the server system 200 (S204). At this time, through the second flow meter 120 and the second thermometer 160 that are disposed here, the outlet flow rate and the outlet temperature of the coolant C may be detected (S205).

The controller 170 may receive the inlet flow rate, the outlet flow rate, the inlet temperature, and the outlet temperature, and detect the differential flow between the inlet flow rate and the outlet flow rate and the temperature difference between the inlet temperature and the outlet temperature (S206).

Next, the method for the controller 170 to control the fans 135 according to flow rate is described with respect to FIG. 2B. FIG. 2B shows a flow chart of the method for controlling the fans 135 according to flow rate, in accordance with some embodiments of the present disclosure.

During S207, the server system 200 is in a normal operating state. At this time, the controller 170 controls the operation speed of the pump 145, so that the inlet flow rate and the outlet flow rate maintain at a set differential pressure to continue the circulation of the coolant C between the liquid cooling system 100 and the server system 200. At this set differential pressure, the liquid cooling system 100 can provide a sufficient flow of the coolant C to the server system 200 according to the set conditions to cool the server system 200. When the pump 145 controls the differential flow between the inlet flow rate and the outlet flow rate (detected in S206 previously) reaches the set differential pressure, the controller 170 starts to record the real-time value of the inlet flow rate and/or the outlet flow rate as the comparison value.

During S208, the server system 200 is in a state where the heat load changes. For example, changes in the number of servers 201 in the server system 200, replacement of servers 201, temporary failure of other water supply systems other than the liquid cooling system 100 connected to the server system 200, or the like may all cause changes in the heat load of the server system 200. When the heat load increases, the heat dissipation requirement of the server system 200 increases, so that the flow demand of the coolant C increases. In addition, a decrease in the inlet flow rate or outlet flow rate may also increase the heat dissipation demand of the server system 200 and the flow demand of the coolant C. At this time, the flow demand increases, which reduces the differential pressure between the inlet and outlet flow, and the controller 170 stops the recording of the real-time flow value of the inlet flow rate and/or the outlet flow rate. In some embodiments, the controller 170 uses the real-time value last recorded in its memory as said comparison value when the real-time value of the inlet flow rate and/or the outlet flow rate stops being recorded. At this time, the controller 170 can also convert the real-time value of the rotating speed of the fans 135 according to this comparison value. The real-time value of the rotating speed of the fan 135 can be used to calculate the set rotating speed of the fans 135 described below.

In S209, using well-known automatic control systems, the pump 145 may increase its operating speed in response to the increase in flow demand, thereby increasing the outlet flow rate of the liquid cooling system 100.

In S210, the controller 170 determines whether the inlet flow rate and/or the outlet flow rate rises to the first constant times the comparison value before the differential flow reaches the set differential pressure. In some embodiments, the first constant is greater than 1. The setting of the first constant can be used to determine whether the change in flow is normal. For example, the pipeline of the coolant C may be slightly blocked over time, and the flow change generated at this time will not rise to the first constant times the comparison value, so it can be excluded from the situation where the heat load increases and needs to be resolved as soon as possible. On the other hand, in the case where the number of servers 201 in the server system 200 changes, the server 201 is replaced, and other water supply systems other than the liquid cooling system 100 connected to the server system 200 temporarily fail, the flow change generated rises to the first constant times the comparison value, so the controller 170 can determine that heat dissipation needs to be performed as soon as possible.

If the controller 170 determines that the inlet flow rate and/or the outlet flow rate increases to the first constant times the comparison value, the process goes to S211. In S211, the rotating speed of each of the fans 135 are increased to be a set rotating speed. The set rotating speed is the second constant times the current rotating speed (the rotating speed before the increase, that is, the real-time value of the rotating speed of said fans 135). In some embodiments, the second constant is greater than 1. Meanwhile, the recorded flow rate in the memory is updated to real-time flow rate.

Next, in S212, through PID calculation and feedforward control, the rotating speed of fans is slightly adjusted to achieve more efficient heat dissipation.

Furthermore, in addition to the above-mentioned method of controlling the fan speed based on the inlet flow rate and/or the outlet flow rate, the embodiments of the present disclosure can further adjust the fan speed by utilizing the temperature difference between the inlet temperature and the outlet temperature (detected in the above-mentioned S206). For example, when the detected temperature difference is greater than a set temperature difference, the controller 170 can determine that the heat load of the server system 200 has increased. Similar to the above-mentioned steps S208 and S209, when it is determined that the heat load has increased, the real-time value of the inlet flow rate or the outlet flow rate is stopped from being recorded and the operating speed of the pump 145 is increased.

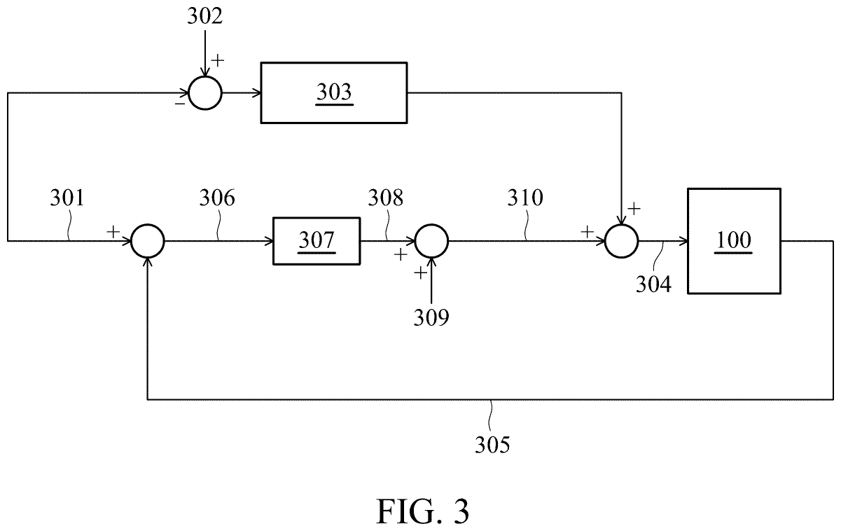

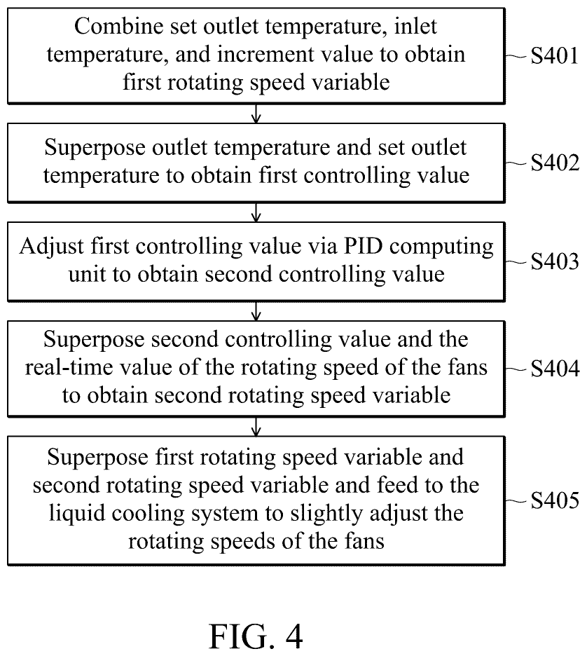

Next, the PID controlling method in step S212 is described with respect to FIG. 3 and FIG. 4. FIG. 3 shows a block diagram of the controller 170 in the liquid cooling system 100, in accordance with some embodiments of the present disclosure. FIG. 4 is a flow chart of the control method corresponding to the block diagram of FIG. 3.

In FIG. 3, the set outlet temperature 301 is the pre-determined supply temperature of the coolant C. First, referring to the loop at the top of FIG. 3, in this loop, which is a feedforward control loop, when each of the fans 135 is operating at the aforementioned set rotating speed, the controller 170 can combine the set outlet temperature 301, the inlet temperature 302 and the increment value 303 to obtain a first rotating speed variable 304 (S401). Specifically, the difference between the set outlet temperature 301 and the inlet temperature 302 may be regarded as the heat load of the server system 200. The increment value 303 may be determined according to this heat load as compensation for the fan speed. For example, when the temperature difference is greater, that is, when the heat load of the server system 200 is greater, the fan speed may be increased in advance to shorten the response time of the controller 170.

Next, referring to the loop at the bottom of FIG. 3, in this loop, first, the outlet temperature 305 and the set outlet temperature 301 are superposed to obtain the first controlling value 306 (S402). The difference between the outlet temperature 305 and the set outlet temperature 301 may be regarded as the basis for determining whether the fan speed should be increased or decreased. The difference is used as the first controlling value 306. The first controlling value 306 is adjusted by the PID computing unit 307 to obtain the second controlling value 308 (S403). Next, the second controlling value 308 and the real-time value 309 of the fan speed (the fan speed at the previous moment) are superposed to obtain the second rotating speed variable 310 (S404). At last, the first rotating speed variable 304 and the second rotating speed variable 310 are superposed and fed to the liquid cooling system 100 to slightly adjust the rotating speed of each of the fans 135 (S405).

In summary, according to some embodiments of the present disclosure, the liquid cooling system 100 can be controlled through the two aspects of flow rate and temperature. When the outlet flow rate increases, it can be determined that the heat-dissipation demand of the server system 200 increases, and the fan speed is controlled to increase. At the same time, by detecting the difference between the outlet temperature and the inlet temperature, the fan speed can be increased in response to the heat load of the server system 200 in advance. In this way, the response time of the controller 170 is effectively reduced, the fluctuation of the water temperature is reduced, and the effect of fan-assisted liquid cooling is improved.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements. While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A liquid cooling system for cooling a server system, comprising:
a first flow meter for detecting an inlet flow rate of coolant from the server system into the liquid cooling system;
a second flow meter for detecting an outlet flow rate of coolant out of the liquid cooling system;
a radiator that includes a plurality of fans, wherein the radiator receives the high-temperature coolant from the server system and operates each of the fans to cool the coolant;
a reservoir that includes at least one pump, wherein the reservoir receives the cooled coolant and feeds it from the liquid cooling system to the server system by operating the pump; and
a controller for detecting a differential flow between the inlet flow rate and the outlet flow rate, and for recording the inlet flow rate or the outlet flow rate in a real-time value as a comparison value;
wherein if the inlet or outlet flow rate rises to a first constant times the comparison value before the differential flow reaches a set differential pressure, the rotating speed of each of the fans is increased.

2. The liquid cooling system as claimed in claim 1, wherein the controller is further used for:
controlling an operation speed of the pump, so that the differential flow reaches the set differential pressure;
wherein when the differential flow reaches the set differential pressure, the controller starts to record the real-time value of the inlet flow rate or the outlet flow rate.

3. The liquid cooling system as claimed in claim 2, further comprising:
a first thermometer for detecting an inlet temperature of the coolant into the liquid cooling system; and
a second thermometer for detecting an outlet temperature of the coolant out of the liquid cooling system;
wherein the controller is further used for:
detecting a temperature difference between the inlet temperature and the outlet temperature;
determining that a heat load of the server system has increased when the temperature difference is greater than a set temperature difference; and
stopping the recording of the real-time value of the inlet flow rate or the outlet flow rate and increasing the operation speed of the pump when the heat load is determined to have increased and the inlet flow rate or the outlet flow rate is determined to have been reduced.

4. The liquid cooling system as claimed in claim 3, wherein the controller uses the real-time value last recorded in a memory as the comparison value when the real-time value of the inlet flow rate or the outlet flow rate stops being recorded.

5. The liquid cooling system as claimed in claim 1, wherein the controller is further used for:
increasing the rotating speed of each of the fans to a set rotating speed;
wherein the set rotating speed is a second constant times the rotating speed before the increase;
wherein both the first constant and the second constant are greater than 1.

6. The liquid cooling system as claimed in claim 5, further comprising:
a first thermometer for detecting an inlet temperature of the coolant from the server system into the liquid cooling system; and
a second thermometer for detecting an outlet temperature of the coolant out of the liquid cooling system;
wherein when each of the fans is rotating at the set rotating speed, the controller is further used for combining a set outlet temperature, the inlet temperature, and an increment value to obtain a first rotating speed variable.

7. The liquid cooling system as claimed in claim 6, wherein the controller is further used for:
superposing the outlet temperature and the set outlet temperature to obtain a first controlling value;
adjusting the first controlling value via a PID computing unit to obtain a second controlling value;
superposing the second controlling value and the real-time value of the rotating speed of the fans to obtain a second rotating speed variable; and
superposing the first rotating speed variable and the second rotating speed variable to slightly adjust the rotating speed of each of the fans.

8. A method for controlling a liquid cooling system for cooling a server system, comprising:
detecting an inlet flow rate of coolant from the server system into the liquid cooling system;
detecting an outlet flow rate of coolant out of the liquid cooling system;
cooling the high-temperature coolant from the server system by operating a plurality of fans via a radiator that includes the fans;
operating at least one pump, so that the cooled coolant is fed from the liquid cooling system to the server system;
detecting a differential flow between the inlet flow rate and the outlet flow rate;
recording the inlet flow rate or the outlet flow rate in a real-time value as a comparison value; and
if the inlet or outlet flow rate rises to a first constant times the comparison value before the differential flow reaches a set differential pressure, the rotating speed of each of the fans is increased.

9. The method for controlling the liquid cooling system as claimed in claim 8, further comprising:
controlling an operation speed of the pump, so that the differential flow reaches the set differential pressure;
wherein when the differential flow reaches the set differential pressure, starting to record the real-time value of the inlet flow rate or the outlet flow rate.

10. The method for controlling the liquid cooling system as claimed in claim 9, further comprising:
detecting an inlet temperature of the coolant into the liquid cooling system;
detecting an outlet temperature of the coolant out of the liquid cooling system;
detecting a temperature difference between the inlet temperature and the outlet temperature;
determining that a heat load of the server system has increased when the temperature difference is greater than a set temperature difference; and
stopping the recording of the real-time value of the inlet flow rate or the outlet flow rate and increasing the operation speed of the pump when the heat load is determined to have increased and the inlet flow rate or the outlet flow rate is determined to have been reduced.

11. The method for controlling the liquid cooling system as claimed in claim 8, further comprising:
increasing the rotating speed of each of the fans to a set rotating speed;
wherein the set rotating speed is a second constant times the rotating speed before the increase;
wherein both the first constant and the second constant are greater than 1.

12. The method for controlling the liquid cooling system as claimed in claim 11, further comprising:
detecting an inlet temperature of the coolant from the server system into the liquid cooling system; and
detecting an outlet temperature of the coolant out of the liquid cooling system;
wherein, when each of the fans is rotating at the set rotating speed, combining a set outlet temperature, the inlet temperature, and an increment value to obtain a first rotating speed variable.

13. The method for controlling the liquid cooling system as claimed in claim 12, further comprising:
superposing the outlet temperature and the set outlet temperature to obtain a first controlling value;
adjusting the first controlling value via a PID computing unit to obtain a second controlling value;
superposing the second controlling value and the real-time value of the rotating speed of the fans to obtain a second rotating speed variable; and
superposing the first rotating speed variable and the second rotating speed variable to slightly adjust the rotating speed of each of the fans.
